(19) United States
(12) Patent Application Publication
(10) Pub. No.: US 2013/0134373 A1
(43) Pub. Date: May 30, 2013

(54) NONVOLATILE RESISTIVE MEMORY ELEMENT WITH A NOVEL SWITCHING LAYER

(71) Applicants: Yun Wang, San Jose, CA (US); Imran Hashim, Saratoga, CA (US); Tony Chiang, Campbell, CA (US)

(72) Inventors: Yun Wang, San Jose, CA (US); Imran Hashim, Saratoga, CA (US); Tony Chiang, Campbell, CA (US)

(73) Assignee: Intermolecular, Inc., San Jose, CA (US)

(21) Appl. No.: 13/305,568

(22) Filed: Nov. 28, 2011

(51) Int. Cl. H01L 45/00

(52) U.S. Cl. 257/2; 438/382; 257/E45.003

(57) ABSTRACT

A nonvolatile resistive memory element has a novel variable resistance layer comprising one or more rare-earth oxides. The rare-earth oxide has a high k value, a high bandgap energy, and the ability to maintain an amorphous structure after thermal anneal processes. Thus, the novel variable resistance layer facilitates improved switching performance and reliability of the resistive memory element.

### BACKGROUND

1. Field of the Invention

This invention relates to nonvolatile resistive memory elements, and more particularly, to a nonvolatile resistive memory element with a novel switching layer and methods for forming the same.

2. Description of the Related Art

Nonvolatile memory elements are used in devices requiring persistent data storage, such as digital cameras and digital music players, as well as in computer systems. Electrically-erasable programmable read only memory (EPROM) and NAND flash are nonvolatile memory technologies currently in use. However, as device dimensions shrink, scaling issues pose challenges for traditional nonvolatile memory technology. This has led to the investigation of alternative nonvolatile memory technologies, including resistive switching nonvolatile memory.

Resistive switching nonvolatile memory is formed using memory elements that are bistable, i.e., having two stable states with different resistances. A bistable memory element can be placed in a high resistance state or a low resistance state by application of suitable voltages or currents. Voltage pulses are typically used to switch the bistable memory element from one resistance state to the other. Subsequently, nondestructive read operations can be performed on the memory element to ascertain the value of a data bit that is stored therein.

As resistive switching memory device sizes shrink, it is important to reduce the required currents and voltages that are necessary to reliably set, reset and/or determine the desired “on” and “off” states of the device, thereby minimizing power consumption of the device, resistive heating of the device, and cross-talk between adjacent devices. In addition, reliable retention of data by such devices for longer periods is highly desirable.

In light of the above, there is a need in the art for nonvolatile resistive switching memory devices having reduced current and voltage requirements and reliable data retention.

### SUMMARY

One or more embodiments of the present invention provide a nonvolatile resistive memory element with a novel switching layer and methods for forming the same. According to embodiments of the invention, a nonvolatile resistive memory element has improved switching performance and reliability due to a novel variable resistance layer comprising one or more rare-earth oxides. The rare-earth oxide of the variable resistance layer has superior material properties compared to materials currently used in the art for variable resistance layers. Specifically, the rare-earth oxide satisfies the three primary material property criteria for variable resistance layers, including a k value greater than 15, a bandgap greater than 4 eV, and the ability to remain amorphous after thermal processing. Suitable rare-earth oxides for forming the variable resistance layer include binary, ternary, and quaternary rare-earth oxides, such as LaLuOx and GdOx.

According to one embodiment of the present invention, a nonvolatile memory element, comprises a first electrode layer, a second electrode layer, and a variable resistance layer disposed between the first electrode layer and the second electrode layer comprising a rare-earth-containing oxide.

According to another embodiment of the present invention, a method of forming a memory device having a memory element includes the steps of forming a first electrode layer of the memory element, forming a variable resistance layer of the memory element on the first electrode layer, wherein the variable resistance layer comprises a rare-earth oxide, and forming a second electrode layer of the memory element above the variable resistance layer.

### BRIEF DESCRIPTION OF THE DRAWINGS

So that the manner in which the above recited features of embodiments of the invention can be understood in detail, a more particular description of embodiments of the invention, briefly summarized above, may be had by reference to the appended drawings. It is to be noted, however, that the appended drawings illustrate only typical embodiments of this invention and are therefore not to be considered limiting of its scope, for the invention may admit to other equally effective embodiments.

FIG. 1 is a graph illustrating bandgap vs. k value for switching layer candidate materials known in the art.

FIG. 2 is a perspective view of a memory array of memory devices, configured according to embodiments of the invention.

FIG. 3A is a schematic cross-sectional view of a memory device, in accordance with an embodiment of the invention.

FIG. 3B schematically illustrates a memory device 200 configured to allow current to flow through the memory device in a forward direction, according to embodiments of the invention.

FIG. 4 sets forth a log-log plot of current versus voltage of a bipolar switching curve for one embodiment of a memory element, according to an embodiment of the invention.

FIG. 5 is a schematic cross-sectional view of a memory device formed from a series of deposited layers, according to embodiments of the invention.

FIG. 6 sets forth a flowchart of method steps in a process sequence for forming a memory device, according to one embodiment of the invention.

For clarity, identical reference numbers have been used, where applicable, to designate identical elements that are common between figures. It is contemplated that features of one embodiment may be incorporated in other embodiments without further recitation.

### DETAILED DESCRIPTION

Materials to be used as the bistable switching layer of a nonvolatile resistive memory element are generally required to have a number of different characteristics, including a relatively high dielectric constant value k, high bandgap energy, and the ability to maintain an amorphous structure during the thermal processing associated with forming a resistive memory element. The more of these characteristics a bistable switching material has, the better suited the material is for use in a nonvolatile resistive memory element as a switching layer. A bistable material that has all of these characteristics enables fabrication of a high-performance nonvolatile resistive memory element.

Dielectric materials having high k values have been correlated with having a higher density of the type of defects that facilitate low switching voltage and low switching current in resistive memory elements. Specifically, the weak bonding associated with high-K dielectric materials is believed to make the presence of the defects and/or oxygen vacancies in the material more likely to be formed and to be more mobile, thereby requiring low switching voltage and current. Accordingly, it is desirable for materials used as a switching layer to have a high k value, for example 15 to 20 or more.

High bandgap energy in bistable switching materials enables more reliable retention of data. Data retention in resistive memory elements for extended periods depends on the bistable switching layer remaining in a particular state, i.e., “on” or “off”. In materials with higher bandgap, for example greater than about 4 electron volts (eV), electrons trapped in a defect are much less likely to escape the defect and alter the state of the memory element.

Bistable switching layers also preferably have an amorphous structure, which is free of grain boundaries. This is because grain boundaries in the bistable switching layer can potentially act as leakage paths for charge carriers. In a bistable switching layer, such leakage paths can provide pathways for trapped electrons or other charge carriers in a resistive memory device, resulting in data loss. It is noted that devices that include resistive memory elements generally undergo one or more thermal processing steps during manufacturing, such as a rapid thermal anneal process for activating diodes. Consequently, materials used for bistable switching layers should be able to maintain a desired amorphous structure throughout such thermal processing.

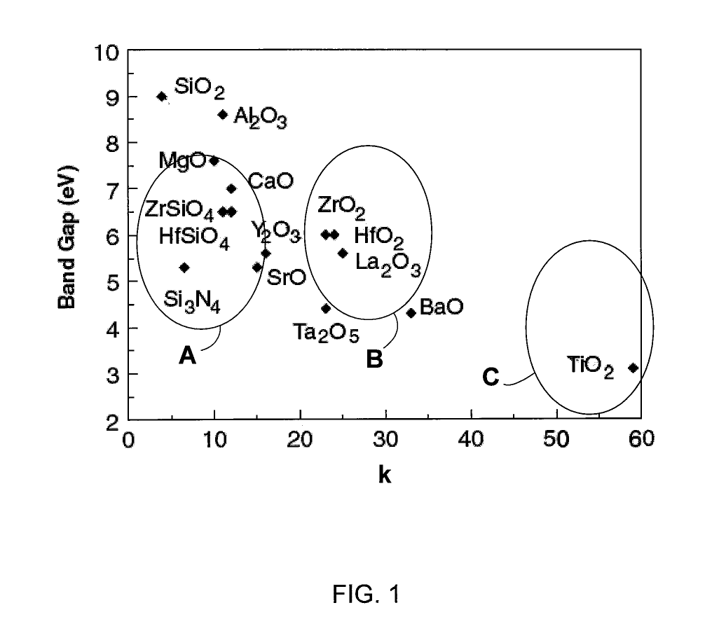

Numerous materials have been explored for possible use in switching layers for nonvolatile resistive memory devices, including various oxides, nitrides, and all of the transition metals, i.e., hafnium, zirconium, titanium, tantalum, and the like. However, none of the materials currently under consideration meet all of the desired characteristics outlined above. The failure of any particular switching layer candidate material currently known in the art to meet all of these criteria is illustrated FIG. 1. FIG. 1 is a graph illustrating bandgap vs. k value for switching layer candidate materials known in the art. Candidate materials included in FIG. 1 are transition metal oxides that, for ease of description, are organized in three general groups: A, B, and C.

Group A includes MgO, CaO, ZrSiO₄, HfSiO₄, Y2O₃, SrO, and Si₃N₄. As shown, the materials making up group A have relatively high bandgap energies that are greater than 5 eV, and are also generally capable of maintaining an amorphous structure even after a 1000° C. thermal process. However, the materials of group A also have relatively low k values, i.e., less than about 15. Group B includes ZrO₂, HfO₂, and La₂O₃, which have k values greater than the desired minimum threshold of 15 to 20 and bandgap energies above the minimum desired 5 eV. Unfortunately, the materials making up group B are also known to lose some or all of their deposited amorphous structure during thermal processing of 1000° C. Group C includes TiO₂, which can maintain an amorphous structure after a 1000° C. processes and has a high k value. However, TiO₂ also has a low bandgap energy of approximately 3 eV, rendering this material impractical for use as a switching layer. Thus, none of the materials currently considered as candidate materials for use in a switching layer of a nonvolatile resistive memory device meets all criteria. Table 1 summarizes the shortcomings of each of groups A, B, and C with respect to the three characteristics of an ideal bistable switching material.

TABLE 1

| Criterion | Group A | Group B | Group C |
|---|---|---|---|
| K > 20 | | X | X |
| E_{g} > 5 eV | X | X | |
| Amorphous after | X | | X |
| 1000° C. anneal | | | |

Embodiments of the invention provide a nonvolatile resistive memory element with a novel variable resistance layer comprising one or more rare-earth oxides, and a method of forming the same. The rare-earth oxide of the variable resistance layer has superior material properties compared to materials currently used in the art for variable resistance layers, and facilitates improved switching performance and reliability of the resistive memory element. Specifically, rare-earth oxides have been demonstrated to have high k values, high bandgap energies, and the ability to maintain an amorphous structure after thermal anneal processes.

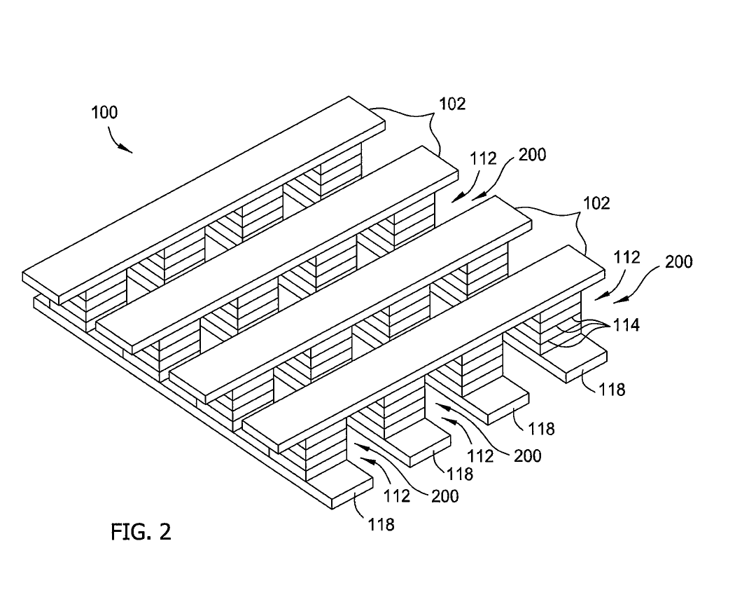

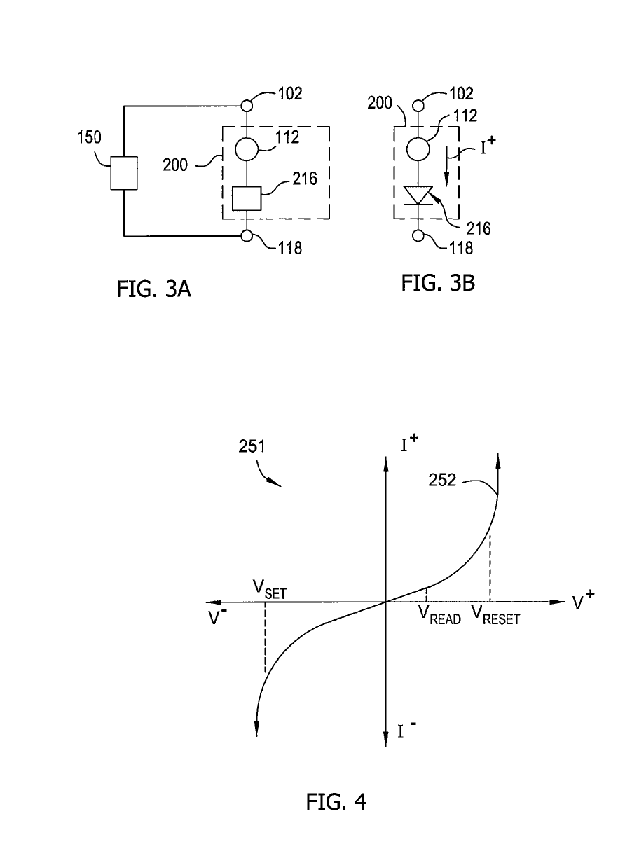

FIG. 2 is a perspective view of a memory array 100 of memory devices 200, configured according to embodiments of the invention. Memory array 100 may be part of a larger memory device or other integrated circuit structure, such as a system-on-a-chip type device. Memory array 100 may be formed as part of a high-capacity nonvolatile memory integrated circuit, which can be used in various electronic devices, such as digital cameras, mobile telephones, handheld computers, and music players. Each of memory devices 200 is a nonvolatile resistive switching memory device that includes a memory element 112 and an optional current steering device 216 (shown in FIGS. 3A, 3B) that is configured to allow or inhibit current flow in different directions through memory element 112. Memory element 112 comprises a novel variable resistance layer comprising one or more rare-earth oxides. Current steering device 216 is shown in FIGS. 3A, 3B and is described below.

Read and write circuitry is connected to memory devices 200 using electrodes 102 and electrodes 118. Electrodes, such as electrodes 102 and electrodes 118, are sometimes referred to as word lines and bit lines, and are used to read and write data into the memory elements 112 in the switching memory devices 200. Individual memory devices 200 or groups of memory devices 200 can be addressed using appropriate sets of electrodes 102 and 118. Memory elements 112 in memory devices 200 may be formed from one or more layers 114 of materials, including a novel switching layer that includes a rare-earth oxide. In addition, memory arrays such as memory array 100 can be stacked in a vertical fashion to make multilayer memory array structures.

FIG. 3A is a schematic cross-sectional view of a memory device 200 in accordance with an embodiment of the invention. Memory device 200 includes memory element 112 and in some embodiments current steering device 216, which are both disposed between the electrodes 102 and 118. In one embodiment, current steering device 216 is an intervening electrical component, such as a p-n junction diode, p-i-n diode, transistor, or other similar device that is disposed between electrode 102 and memory element 112, or between the electrode 118 and memory element 112. In some embodiments, current steering device 216 may include two or more layers of semiconductor material, such as two or more doped silicon layers, that are configured to allow or inhibit the current flow in different directions through the memory element 112. In addition, read and write circuitry 150 is coupled to memory device 200 via electrodes 102 and 118 as shown. Read and write circuitry 150 is configured to both sense the resistance state and set the resistance state of memory device 200.

FIG. 3B schematically illustrates memory device 200 configured to allow current to flow through memory device 200 in a forward direction (“I⁺”), according to embodiments of the invention. However, due to the design of current steering device 216, a reduced current can also flow in the opposing direction through the device by the application of a reverse bias to the electrodes 102 and 118.

During a read operation, read and write circuitry 150 applies a read voltage V_{READ}, e.g., +0.5 volts (V), across resistive switching memory element 112 using an appropriate set of electrodes 102 and 118 in memory array 100. Read and write circuitry 150 senses the resultant current passing through memory device 200. A relatively high “on” current value (I_{ON}) indicates that memory element 112 is in its low resistance state, and a relatively low “off” current value (I_{OFF}) indicates that memory element 112 is in its high resistance state. Depending on its history, the particular memory element 112 that is addressed in this way may be in either a high resistance state (HRS) or a low resistance state (LRS). The resistance of memory element 112 therefore determines what digital data is being stored therein. For example, if memory element 112 is in the high resistance state, memory element 112 may be said to contain a logical zero (i.e., a “0” bit). If, on the other hand, memory element 112 is in the low resistance state, memory element 112 may be said to contain a logical one (i.e., a “1” bit).

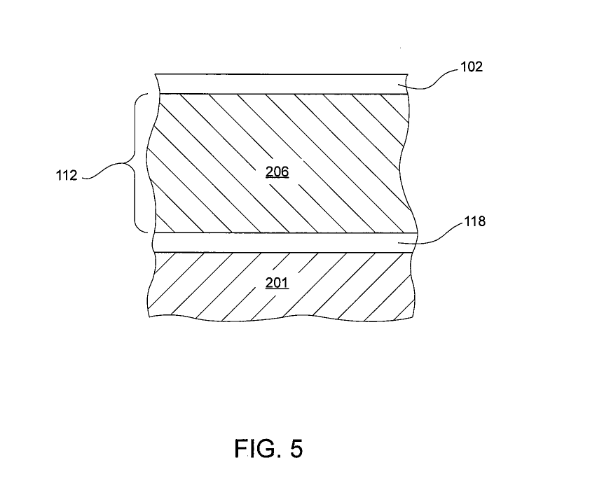

During a write operation, the resistive state of a particular memory element 112 in memory array 100 is changed by application of suitable write signals to an appropriate set of electrodes 102 and 118 by read and write circuitry 150. In some embodiments, to affect such a change, bipolar switching is used, where opposite polarity set and reset voltages are used to alter the resistance of a selected memory element 112 between high and low resistance states. FIG. 4 sets forth a log-log plot 251 of current (I) versus voltage (V) of a bipolar switching curve 252 for one embodiment of memory element 112, and thus illustrates typical threshold values used to set and reset the contents of memory element 112. For example, memory element 112 may initially be in a high resistance state (e.g., storing a logical “zero”). To store a logical “one” in memory element 112, memory element 112 is placed into its low-resistance state. This may be accomplished by using read and write circuitry 150 to apply a set voltage V_{sET} (e.g., −2 V to −4 V) across electrodes 102 and 118. In one embodiment, applying a negative V_{SET} voltage to memory element 112 causes memory element 112 to switch to its low resistance state. In this region, the memory element 112 is changed so that, following removal of the set voltage V_{SET}, memory element 112 is characterized by a low resistance state. Conversely, to store a logical “zero” in memory element 112, the memory element can once again be placed in its high resistance state by applying a positive reset voltage V_{RESET} (e.g., +2 V to +5 V) to memory element 112. When read and write circuitry 150 applies V_{RESET} to memory element 112, memory element 112 enters its high resistance state. When reset voltage V_{RESET} is removed from memory element 112, memory element 112 will once again be characterized by high resistance when read voltage V_{READ} is applied. While the discussion of the memory element 112 herein primarily provides bipolar switching examples, some embodiments of the memory elements 112 may use unipolar switching, where the set and reset voltages have the same polarity, without deviating from the scope of the invention described herein.

It is believed that the change in the resistive state of the memory element 112 may be “trap-mediated,” i.e., due to the redistribution or filling of traps or defects in a variable resistance layer of memory element 112 when memory device 200 is reverse biased. The defects or traps, which are commonly formed during the deposition and/or post-processing of the variable resistance layer 206, are often created by a non-stoichiometric material composition of the variable resistance layer. Embodiments of a variable resistance layer 206 is described below in conjunction with FIG. 5.

It is noted that materials selected for variable resistance layer 206 that include rare-earth oxides having a k value greater than 15 and an amorphous structure after thermal processing facilitate the use of a lower reset voltage V_{RESET} and set voltage V_{SET} during operation. Accordingly, resistive switching memory devices configured with such a variable resistance layer may reduce power consumption, resistive heating, and cross-talk between adjacent devices.

In an effort to prepare the memory element 112 for use, it is common to apply a forming voltage V_{FORM} at least once across the electrodes 102, 118 to “burn-in” each memory device 200 of memory array 100. It is believed that the application of forming voltage V_{FORM}, which is typically significantly greater than the V_{RESET} and V_{SET} voltages, causes the defects that are formed within the variable resistance layer 206 during the device fabrication process to move, align and/or collect within various regions of the layer, causing variable resistance layer 206 to consistently and reliably switch between the “on” and “off” resistive states throughout the memory element's life. In one embodiment, forming voltage V_{FORM} is between about 1 and about 5 times greater than the V_{RESET} or V_{SET} voltage. In one example, the forming voltage is between about 1.4 and about 2.5 times greater than the V_{RESET} or V_{SET} voltage. In one example, the forming voltage is between about 3 and about 7 volts. However, it is noted that in some cases it is desirable to form memory element 112 so that the application of a forming voltage is not required at all to assure that the device will perform as desired throughout its life.

FIG. 5 is a schematic cross-sectional view of memory device 200 formed from a series of deposited layers, according to embodiments of the invention. In the embodiment illustrated in FIG. 5, memory device 200 is formed over, or integrated with and distributed over, portions of a surface of a substrate 201 (e.g., silicon substrate, SOI substrate). It is noted that relative directional terms used herein with regard to embodiments of the invention are for purposes of description only, and do not limit the scope of the invention. Specifically, directional terms such as “over,” “above,” “under,” and the like are used under the assumption that the substrate on which embodiments are formed is a “bottom” element and is therefore “under” elements of the invention formed thereon. In one embodiment, memory device 200 comprises a memory element 112 disposed between electrodes 102, 118 and comprising variable resistance layer 206. In other embodiments, memory device further comprises an optional intermediate electrode and optional current steering device 216 disposed between electrode 118 and variable resistance layer 206.

Electrodes 102, 118 are formed from conductive materials that have a desirable work function tailored to the bandgap of the material making up variable resistance layer 206. In some configurations, electrodes 102, 118 are formed from different materials so that electrodes 102, 118 have a work function that differs by a desired value, e.g., 0.1 eV, 0.5 eV, 1.0 eV, etc. For example, in one embodiment, electrode 102 is comprised of TiN, which has a work function of 4.5-4.6 eV, while electrode 118 can be n-type polysilicon, which has a work function of approximately 4.1-4.15 eV. Other electrode materials suitable for use in electrode 102 and/or electrode 118 include p-type polysilicon (4.9-5.3 eV), n-type polysilicon, transition metals, transition metal alloys, transition metal nitrides, transition metal carbides, tungsten (4.5-4.6 eV), tantalum nitride (4.7-4.8 eV), molybdenum oxide (˜5.1 eV), molybdenum nitride (4.0-5.0 eV), iridium (4.6-5.3 eV), iridium oxide (˜4.2 eV), ruthenium (˜4.7 eV), and ruthenium oxide (˜5.0 eV). Other potential electrode materials include a titanium/aluminum alloys (4.1-4.3 eV), nickel (−5.0 eV), tungsten nitride (−4.3-5.0 eV), tungsten oxide (5.5-5.7 eV), aluminum (4.2-4.3 eV), copper or silicon-doped aluminum (4.1-4.4 eV), copper (˜4.5 eV), hafnium carbide (4.8-4.9 eV), hafnium nitride (4.7-4.8 eV), niobium nitride (˜4.95 eV), tantalum carbide (approximately 5.1 eV), tantalum silicon nitride (˜4.4 eV), titanium (4.1-4.4 eV), vanadium carbide (˜5.15 eV), vanadium nitride (˜5.15 eV), and zirconium nitride (˜4.6 eV). In some embodiments, electrode 102 is a metal, metal alloy, metal nitride or metal carbide formed from an element selected from a group of materials consisting of titanium (Ti), tungsten (W), tantalum (Ta), cobalt (Co), molybdenum (Mo), nickel (Ni), vanadium (V), hafnium (Hf) aluminum (Al), copper (Cu), platinum (Pt), palladium (Pd), iridium (Ir), ruthenium (Ru), and combinations thereof. In one example, the electrode 102 comprises a metal alloy selected from the group of a titanium/aluminum alloy (TiₓAl_{y}), or a silicon-doped aluminum (AlSi).

Variable resistance layer 206 comprises a dielectric material that can be switched between two or more stable resistive states. According to embodiments of the invention, variable resistance layer 206 includes a rare-earth oxide having a high bandgap, e.g., bandgap >4 eV, a k value of at least 15, and an amorphous structure after high temperature anneal processes. In some embodiments, variable resistance layer 206 has a thickness of between about 10 and about 100 Å.

Rare-earth oxides suitable for use in variable resistance layer 206 may include oxides of any of the rare-earth chemical elements, specifically: lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), and yttrium (Y). Such rare-earth oxides include rare-earth binary oxides, which consist of a single rare-earth chemical element bound to oxygen, rare-earth ternary oxides, which consist of a rare-earth chemical element and one additional element bound to oxygen, and rare-earth quaternary oxides, which consist of a rare-earth chemical element and two additional elements bound to oxygen. Examples of rare-earth ternary oxides suitable for use as variable resistance layer 206 include lanthanum lutetium oxide (LaLuOₓ), gadolinium silicate oxide (GdSiOₓ), and numerous rare-earth scandates (YScO₃, LaScO₃, PrScO₃, NdScO₃, SmScO₃, GdScO₃, TbScO₃, DyScO₃, HoScO₃, ErScO₃).

For example, LaLuOₓ has been demonstrated in the literature to have a k value of approximately 32, a bandgap of approximately 5.2 eV, and an amorphous structure after a rapid thermal anneal (RTA) process at 1000° C., and therefore meets the three primary criteria for an ideal variable resistance layer. In another example, GdOₓ and GdSiOₓ have each been demonstrated in the literature to have a k value of approximately 15 to 17, a bandgap of approximately 5 eV, and an amorphous structure after a rapid thermal anneal (RTA) process at 1000° C., and therefore also meet the three primary criteria for an ideal variable resistance layer. In yet other examples, the rare-earth scandates YscO₃, LaScO₃, PrScO₃, NdScO₃, SmScO₃, GdScO₃, TbScO₃, DyScO₃, HoScO₃, and ErScO₃ have been demonstrated in the literature to have k values of 20 to 35, bandgaps 5.6 eV, and amorphous structure after a rapid thermal anneal (RTA) process at 1000° C. Thus these rare-earth scandates also meet the three primary criteria for an ideal variable resistance layer.

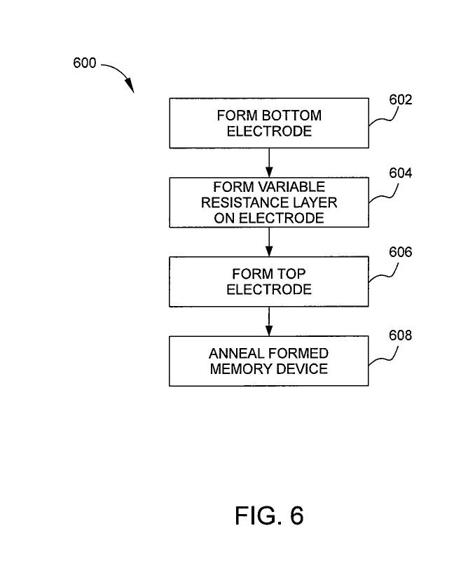

FIG. 6 sets forth a flowchart of method steps in a process sequence 600 for forming memory device 200, according to one embodiment of the invention. Although the method steps are described in conjunction with memory device 200 in FIG. 5, persons skilled in the art will understand that formation of other resistive switching memory devices using process sequence 600 is within the scope of the invention.

As shown, method 600 begins at step 602, in which electrode 118 is formed. In one embodiment, electrode 118 is a highly doped polysilicon layer that is formed on substrate 201 using a conventional CVD or ALD type polysilicon deposition technique. In some cases, an optional native oxide layer removal step may be performed after forming electrode layer 118 by use of a wet chemical processing technique, or conventional dry clean process that is performed in a plasma processing chamber. In one example, electrode 118 comprises polysilicon, and is between about 50 and about 5000 Å thick.

In step 604, variable resistance layer 206 is formed on electrode 118 using a deposition process. Variable resistance layer 206 comprises a rare-earth oxide suitable for use as a variable resistance layer, a number of which are listed above. Embodiments of the invention include various methods of depositing variable resistance layer 206, and depend in part on what specific rare-earth oxide is being deposited: physical vapor deposition (PVD); metal deposition of the desired rare-earth chemical element followed by an oxidation process; metalorganic chemical vapor deposition (MOCVD); and atomic layer deposition (ALD).

In some embodiments, non-reactive PVD, or sputtering, of the desired rare-earth oxide directly deposits a rare-earth oxide layer for variable resistance layer 206. In an alternative embodiment, metal deposition techniques may be used to deposit a layer of the desired rare-earth chemical element, for example, PVD, e-beam evaporation, or other deposition processes known in the art. A subsequent oxidation process then oxidizes the deposited rare-earth layer. In other embodiments, MOCVD may be used to directly deposit the desired rare-earth oxide in step 604. In yet other embodiments, multiple cycles of an ALD process are used to deposit a rare-earth oxide having a desired thickness.

In one embodiment, a LaLuO₃ thin film is deposited on a substrates by means of pulsed laser deposition (PLD) using a stoichiometric ceramic target. The target comprises a milled stoichiometric mixture of Lu₂O₃ (Alfa Aesar, 99.99%) and Lu₂O₃ (Alfa Aesar, 99.999%) powders with a molar ratio of 1:1. In an example embodiment, the ground powder is dried and fired at 1300° C. in air for 12 hours, reground, and pressed with a uniaxial press (3 tons) into pellets. The pellets are sintered at 1500° C. in air for 10 hours. In some embodiments, in order to increase the density of the target material for the PLD process, the pellets are subsequently sintered at 1600° C. in air for 12 h. PLD deposition at a temperature of 450° C. in a 2×10⁻³ mbar oxygen ambient then forms variable resistance layer 206. It is noted that the rare-earth scandates listed above may also be deposited via PLD.

In another embodiment, a Gd₂O₃ film is deposited by e-beam evaporation. Specifically, a Pfeiffer Vacuum Classic 580 tool deposits variable resistance layer 206 from granular Gd₂O₃ with the addition of molecular nitrogen. To ensure that variable resistance layer 206 has an amorphous structure, temperature of the substrate may be maintained below 50° C. during the deposition process.

In yet another embodiment, LaLuO₃ is deposited by molecular-beam epitaxy (MBE). In such an embodiment, post dielectric anneal (PDA) may be introduced in conjunction with forming gas at 400° C. to improve the interface between variable resistance layer 206 and electrode 118.

In some embodiments, rare-earth ternary oxides are deposited using an ALD process. In one exemplary process, ALD is performed at 300° C. with water vapor and an appropriate precursor on a hydrofluoric acid (HF) treated surface. For the deposition of lanthanum, lanthanum trisN,N-di-iso-propylformamidinate is used, for the deposition of lutetium, lutetium trisN,N-diethylformamidinate is used, and for deposition of scandium, scandium trisN,N-diethylacetamidinate is used. In one embodiment, an ALD deposition sequence of one layer of LaLuO₃ alternated with one layer of M₂O₃, where M=Lu or Sc, produces an amorphous variable resistance layer 206 of LaLuO₃ or LaScO₃. The two ALD deposition processes are repeated until a variable resistance layer 206 of the desired thickness is formed.

In step 606, electrode 102 is formed on variable resistance layer 206 as shown in FIG. 5 using one or more of the materials suitable for electrode 102 listed above in conjunction with FIG. 5. The electrode 102 layer may be formed using a deposition process, such as a PVD, CVD, ALD or other similar process. In one embodiment, the electrode layer 102 is between about 500 Å and 1 μm thick.

In step 608, formed memory device 200 is annealed. Temperature and duration of the anneal process is a function of the configuration of memory device 200 as well as the materials included in memory device 200. For example, in some embodiments, the anneal process takes place at a temperature of greater than about 550° C. In other embodiments, the anneal process takes place at a temperature of greater than about 600° C. In yet other embodiments, the anneal process takes place at a temperature of greater than about 1000° C. Duration of anneal process can also vary greatly, e.g. varying between about 30 seconds and 20 minutes depending on the configuration of memory device 200. Furthermore, vacuum anneals, oxygen anneals, anneals using gas mixtures, such as a hydrogen/argon mixture, and other anneal processes known in the art fall within the scope of the invention. Similarly, multiple thermal processing steps may be performed on memory device 200 without exceeding the scope of the invention. For example, a thermal process may be performed during or after multiple steps of method 600.

While embodiments of the invention are described herein in terms of resistive switching memory elements that are used to form memory arrays, embodiments of the present invention can be applied to other resistive memory devices without deviating from the basic scope of the invention described herein.

In sum, embodiments of the invention provide a nonvolatile resistive memory element with a novel variable resistance layer comprising one or more rare-earth oxides, and a method of forming the same. The rare-earth oxide of the variable resistance layer has superior material properties compared to materials currently used in the art for variable resistance layers, thereby facilitating improved switching performance and reliability of the resistive memory element.

While the foregoing is directed to embodiments of the present invention, other and further embodiments of the invention may be devised without departing from the basic scope thereof, and the scope thereof is determined by the claims that follow.

1. A nonvolatile memory element, comprising:
a first electrode layer;
a second electrode layer; and
a variable resistance layer disposed between the first electrode layer and the second electrode layer comprising a rare-earth-containing oxide.

2. The nonvolatile memory element of claim 1, wherein the rare-earth-containing oxide comprises at least one rare-earth chemical element.

3. The nonvolatile memory element of claim 2, wherein the at least one rare-earth chemical element is selected from the group consisting of lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), and yttrium (Y).

4. (canceled)

5. The nonvolatile memory element of claim 2, wherein the rare-earth-containing oxide comprises oxygen, a rare-earth chemical element, and a third chemical element.

6. The nonvolatile memory element of claim 5, wherein the third chemical element comprises silicon.

7. The nonvolatile memory element of claim 1, wherein the rare-earth-containing oxide comprises at least two rare-earth chemical elements.

8. The nonvolatile memory element of claim 7, wherein the rare-earth-containing oxide comprises scandium (Sc) and another rare-earth chemical element.

9. The nonvolatile memory element of claim 1, wherein the rare-earth-containing oxide is deposited by one of a pulsed laser deposition process, an e-beam evaporation process, a molecular-beam epitaxy process and an atomic layer deposition process.

10. The nonvolatile memory element of claim 9, wherein the rare-earth-containing oxide comprises LaLuO₃ deposited by a pulsed laser deposition process.

11. The nonvolatile memory element of claim 9, wherein the rare-earth-containing oxide comprises Gd₂O₃ deposited by an e-beam evaporation process.

12. The nonvolatile memory element of claim 9, wherein the rare-earth-containing oxide comprises LaLuO₃ or LaScO₃ deposited by an atomic layer deposition process.

13. The nonvolatile memory element of claim 1, wherein the variable resistance has a thickness of between about 10 Å and about 100 Å.

14-20. (canceled)
